(19) United States
(12) Patent Application Publication
(10) Pub. No.: US 2024/0228706 A1
(43) Pub. Date: Jul. 11, 2024

(54) CURABLE SILICONE COMPOSITION

(71) Applicant: DuPont Toray Specialty Materials Kabushiki Kaisha, Tokyo (JP)

(72) Inventors: Rikuto OTSUKA, Ichihara-shi (JP); Shunya TAKEUCHI, Ichihara-shi (JP); Sosuke Yamaguchi, Ichihara-shi (JP)

(21) Appl. No.: 18/392,078

(22) Filed: Dec. 21, 2023

(30) Foreign Application Priority Data
Dec. 28, 2022 (JP) 2022-21228

(51) Int. Cl. C08G 77/12; C08G 77/00; C08G 77/08; C08G 77/20; C08K 3/22; C08K 5/5425; C08L 83/04

(52) U.S. Cl. CPC C08G 77/12; C08G 77/08; C08G 77/20; C08G 77/80; C08K 3/22; C08K 5/5425; C08L 83/04; C08K 2003/2241; C08L 2203/20; C08L 2205/025; C08L 2205/03

(57) ABSTRACT

A cured product having a low RI and high hardness, and to provide a curable silicone composition that can be rapidly cured at low temperatures. The curable silicone composition according to the present invention comprises a resinous organopolysiloxane that has an aryl-containing group content of 0 to less than 10 mol % and that has 2 or more Si-bonded alkenyl groups, a resinous organohydrogenpolysiloxane that has an aryl-containing group content of 10 mol % or more and that has 2 or more Si-bonded H, and a hydrosilylation reaction catalyst, wherein the amount of linear organopolysiloxane having 2 or more Si-bonded alkenyl groups in the composition is 0 to 3% by mass based on the total mass of all organopolysiloxane components in the composition, and the (total number of mols of Si-bonded H in the composition)/(total number of mols of Si-bonded alkenyl groups in the composition)>0.5.

### CROSS-REFERENCE TO RELATED APPLICATIONS

This application claims priority pursuant to 35 U.S.C. 119(a) to Japanese Application No. 2022-212280, filed Dec. 28, 2022, which application is incorporated herein by reference in its entirety.

### DESCRIPTION

### Technical Field

The present disclosure relates to a curable composition, to a cured product thereof, to a reflective material for an optical semiconductor device which comprises said cured product, and to an optical semiconductor device equipped with the reflective material.

### BACKGROUND ART

Cured products of curable silicone compositions that are cured via a hydrosilylation reaction are known to have a variety of properties such as exceptional heat resistance, cold resistance, electrical insulation properties, weather resistance, water repellency, and transparency. A variety of curable silicone compositions are thus widely used in various industries and are also used as optical materials.

For example, Patent Document 1 states that a curable organopolysiloxane composition containing a methyl-based organopolysiloxane is used as an encapsulant for an optical semiconductor device.

Patent Document 2 (Example 6) discloses an addition curing type of silicone composition comprising: 100 parts by mass of a methyl-based silicone resin represented by average unit formula: (ViMe₂SiO_{1/2})_{0.06}(Me₃SiO_{1/2})_{0.36}(Si_{4/2})_{0.58}; 41.33 parts by mass of a branched organohydrogenpolysiloxane represented by average structural formula: (HMe₂SiO_{1/2})₂(Me₂SiO_{2/2})₁₀₄(MePh₂SiO_{1/2})_{4.3}(HSi_{3/2})_{4.3}; 20 parts by mass of a silicone oil represented by average structural formula: (ViMe₂SiO_{1/2})₂(Ph₂SiO_{2/2})₆(Me₂SiO_{2/2})₁₀₄; and 13.8 parts by mass of a branched organohydrogenpolysiloxane represented by formula: (HMe₂SiO_{1/2})₄(PhSiO_{3/2})₂.

Patent Document 3 (Example 4) discloses a composition comprising: 40 g of a represented compound by formula A: chemical (ViMe₂SiO_{1/2})(Me₃SiO_{1/2})(Me₂SiO_{2/2})₄SiO_{4/2})₈; 60 g of a compound represented by chemical formula B: (ViMe₂SiO_{1/2}) (Me₃SiO_{1/2})₄(Me₂SiO_{2/2})(SiO_{4/2})₅; 20 g of a compound represented by chemical formula E: (HMe₂SiO_{1/2})₂(Ph₂SiO_{2/2}); 2 g of a compound represented by chemical formula G: (HMe₂SiO_{1/2})₃(PhSiO_{3/2}); and 1 g of a compound represented by chemical formula D:

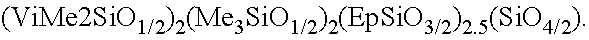

Methyl-based organopolysiloxanes such as those used in the above patent documents usually have a refractive index (RI) lower than that of phenyl-based organopolysiloxanes. Methyl-based organopolysiloxanes are thus promising candidate materials as matrix materials for white reflective materials in optical semiconductor devices.

However, the hardness and toughness (crack resistance) of methyl-based organopolysiloxanes are inferior to those of phenyl-based organopolysiloxanes. When the crosslinking density of methyl-based organopolysiloxanes is increased in an attempt to overcome such drawbacks, the resulting cured product will have higher hardness but is sometimes too brittle for typical applications. Adding a reinforcing agent such as an inorganic filler has been entertained as another method for increasing the hardness of methyl-based organopolysiloxanes. However, the addition of inorganic fillers usually leads to a cured product with attenuated optical properties and lower transmittance or reduced reflectance, as well as a greater silicone composition viscosity.

### PRIOR ART DOCUMENTS

### Patent Documents

[Patent Document 1] Japanese Unexamined Patent Publication No. 2012-012433
[Patent Document 2] Japanese Unexamined Patent Publication No. 2016-204423
[Patent Document 3] Japanese Unexamined Patent Publication No. 2016-520679

### SUMMARY OF THE INVENTION

### Problems to be Solved by the Invention

An objective of the present invention is to provide a cured product having a low RI and high hardness, and to provide a curable silicone composition that can be cured rapidly and at low temperatures. Another objective of the present invention is to provide a cured product having a low RI, high hardness, and a high reflectance, and to provide a curable silicone composition that can be cured rapidly and at low temperatures. Yet another objective of the present invention is to provide a reflective material for an optical semiconductor device that comprises the cured product of said composition, and an optical semiconductor device equipped with the reflective material for an optical semiconductor device.

### Means for Solving the Problems

To solve the above problems, the present invention provides the following curable silicone composition.

A curable silicone composition, comprising:
(A-1) a resinous organopolysiloxane having at least 2 silicon atom-bonded alkenyl groups per molecule, that is represented by the following average unit formula:

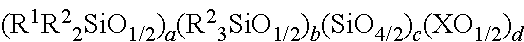

(in the formula,
R¹ is an alkenyl group,
R² is a monovalent hydrocarbon group having no aliphatic unsaturated carbon bonds,
wherein the amount of silicon atom-bonded aryl-containing groups is 0 mol % to less than 10 mol % based on the total number of mols of all silicon atom-bonded organic groups,
X is a hydrogen atom or an alkyl group, and
a, b, c and d represent the molar ratio of each unit, where 0<a≤0.7, 0<b≤0.8, 0<c≤0.7, 0≤d≤0.2, and a+b+c=1.0);
and
(B-1) a resinous organohydrogenpolysiloxane that has at least 2 silicon atom-bonded hydrogen atoms per molecule but does not have any silicon atom-bonded alkenyl groups, wherein the amount of silicon atom-bonded aryl-containing groups is 10 mol % or more based on the total number of mols of all silicon atom-bonded organic groups; and
(C) a hydrosilylation reaction catalyst,
and wherein
the amount of (A-2) linear organopolysiloxane having at least 2 silicon atom-bonded alkenyl groups per molecule in the composition is 0 to 3% by mass based on the total mass of all organopolysiloxane components contained in the composition, and
(total number of mols of silicon atom-bonded hydrogen atoms contained in the composition)/(total number of mols of silicon atom-bonded alkenyl groups contained in the composition)>0.5.

The present invention provides a cured product of the above curable silicone composition.

The present invention provides a reflective material for optical semiconductor devices that comprises said cured product.

The present invention provides an optical semiconductor device that is equipped with the reflective material for optical semiconductor devices.

### Effects of the Invention

An effect of the curable silicone composition according to one embodiment of the present invention is that it can be cured rapidly and at low temperatures, and the cured product has a low RI and high hardness. An effect of the curable silicone composition according to another embodiment of the present invention is that it can be cured rapidly and at low temperatures, and the cured product has a low RI, high hardness, and a high reflectance.

### MODE FOR CARRYING OUT THE INVENTION

### Component (A-1): Resinous Organopolysiloxane Having at Least 2 Silicon Atom-Bonded Alkenyl Groups Per Molecule

Component (A-1) is a resinous organopolysiloxane having at least 2 silicon atom-bonded alkenyl groups per molecule, represented by the following average unit formula.

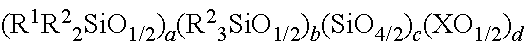

In the formula, R¹ is an alkenyl group; R² is a monovalent hydrocarbon group having no aliphatic unsaturated carbon bonds, wherein the amount of silicon atom-bonded aryl-containing groups is 0 mol % to less than 10 mol % based on the total number of mols of all silicon atom-bonded organic groups; X is a hydrogen atom or an alkyl group; and

a, b, c and d represent the molar ratio of each unit, where 0<a≤0.7, 0<b≤0.8, 0<c≤0.7, 0≤d≤0.2, and a+b+c=1.0.

The curable silicone composition of the present invention may contain one kind of component (A-1), or may contain two or more kinds of component (A-1).

As used in the present specification, “resinous organopolysiloxane” means an organopolysiloxane that comprises at least 1 unit selected from T units (RSiO_{3/2}) (in the formula, R is a monovalent hydrocarbon group or a hydrogen atom) and Q units (SiO_{4/2}) in the molecular structure. The resinous organopolysiloxane may have a branched structure, a three-dimensional network structure, or a combination thereof.

As used in the present specification, “aryl-containing groups” mean aryl groups, hydrocarbon groups partially containing an aryl group, or any of these aryl groups and hydrocarbon groups in which some or all of the hydrogen atoms have been substituted with halogen atoms such as fluorine, chlorine, and bromine atoms; as used in the present specification, “silicon atom-bonded aryl-containing groups” means said “aryl-containing groups” that are bonded directly to a silicon atom. Examples of aryl-containing groups include C6-20 aryl groups such as phenyl, tolyl, xylyl, and naphthyl groups; C7-20 aralkyl groups such as benzyl, phenethyl, and phenylpropyl groups; and any of these groups in which some or all of the hydrogen atoms have been substituted with halogen atoms such as fluorine, chlorine, and bromine atoms.

As used in the present specification, “organic groups” are groups containing at least one carbon atom. “Silicon atom-bonded organic groups” mean organic groups that are directly bonded to a silicon atom without any intervening siloxane bonds (—O—Si—).

Examples of the alkenyl group represented by R¹ in the average unit formula for component (A-1) include C2-12 alkenyl groups such as vinyl, allyl, butenyl, pentenyl, hexenyl, heptenyl, octenyl, nonenyl, decenyl, undecenyl, and dodecenyl groups, as well as these groups in which some or all of the hydrogen atoms have been substituted with halogen atoms such as fluorine, chlorine, and bromine atoms, where C2-6 alkenyl groups are preferred, and vinyl groups are especially preferred.

Examples of monovalent hydrocarbon groups having no aliphatic unsaturated carbon bonds, as represented by R² of the average unit formula for component (A-1), include C1-12 alkyl groups such as methyl, ethyl, propyl, isopropyl, butyl, isobutyl, tert-butyl, pentyl, neopentyl, hexyl, cyclohexyl, heptyl, octyl, nonyl, decyl, undecyl, and dodecyl groups; C6-20 aryl groups such as phenyl, tolyl, xylyl, and naphthyl groups; C7-20 aralkyl groups such as benzyl, phenethyl, and phenylpropyl groups; and any of these groups in which some or all of the hydrogen atoms have been substituted with halogen atoms such as fluorine, chlorine, and bromine atoms. R² is preferably a C1-6 monovalent hydrocarbon group having no aliphatic unsaturated carbon bonds, more preferably a C1-6 alkyl group, and especially preferably a methyl group. In one embodiment, R² is a monovalent hydrocarbon group other than an aryl-containing group.

In component (A-1), the amount of silicon atom-bonded aryl-containing groups is 0 mol % to less than 10 mol % based on the total number of mols of all silicon atom-bonded organic groups. Specifically, in component (A-1), there either are no silicon atom-bonded aryl-containing groups or, in cases where silicon atom-bonded aryl-containing groups are present, the amount of the silicon atom-bonded aryl-containing groups is less than 10 mol % of all silicon atom-bonded organic groups. In the above average unit formula, R¹ and R² in component (A-1) all correspond to all silicon atom-bonded organic groups. The amount of silicon atom-bonded aryl-containing groups in component (A-1), based on the total number of mols of all silicon atom-bonded organic groups, is 0 mol % to less than 10 mol %, preferably 0 mol % to 5 mol %, more preferably 0 mol % to 1 mol %, and even more preferably 0 mol %. Ensuring that the amount of silicon atom-bonded aryl-containing groups in component (A-1) is 0 mol % to less than mol %, based on the total number of mols of all silicon atom-bonded organic groups, will allow cured products that have been formed from the curable silicone composition to have a low refractive index (RI).

In the average unit formula of component (A-1), X is a hydrogen atom or an alkyl group. The alkyl group represented by X is preferably a C1-3 alkyl group, specific examples of which include methyl, ethyl, and propyl groups.

In the average unit formula of component (A-1), a is in the range of 0<a≤0.7, preferably in the range of 0.01≤a≤0.7, more preferably in the range of 0.05≤a≤0.6, and even more preferably in the range of 0.1≤a≤0.5. In the formula, b is in the range of 0<b≤0.8, preferably in the range of 0.01≤b≤0.6, more preferably in the range of 0.05≤b≤0.5, and even more preferably in the range of 0.1≤b≤0.4. In the formula, c is in the range of 0<c≤0.7, preferably in the range of 0.2≤c≤0.6, more preferably in the range of 0.3≤c≤0.5, and even more preferably in the range of 0.35≤c≤0.45. In the formula, d is in the range of 0≤d<0.2, preferably in the range of 0≤d<0.15, more preferably in the range of 0≤d<0.1, and even more preferably in the range of 0≤d≤0.05.

In one embodiment of the present invention, the amount of component (A-1) contained in the curable silicone composition, based on the total mass of all organopolysiloxane components contained in the composition, is preferably 20% by mass or more, more preferably 30% by mass or more, and even more preferably 40% by mass or more, while the amount is preferably no more than 90% by mass, more preferably no more than 80% by mass, even more preferably no more than 60% by mass, and especially preferably no more than 50% by mass.

In one embodiment of the present invention, component (A-1) has a molecular weight of 500 or more. The weight-average molecular weight (Mw) of component (A-1) is not particularly limited, but is preferably 1000 or more, more preferably 1500 or more, and even more preferably 2000 or more, and is preferably no more than 100,000, more preferably no more than 70,000, and even more preferably no more than 50,000. As used in the present specification, the weight-average molecular weight (Mw) is the value calculated on the basis of standard polystyrene, as determined by gel permeation chromatography (GPC).

### Component (A-2): Linear Organopolysiloxane Having at Least 2 Silicon Atom-Bonded Alkenyl Groups Per Molecule

In the curable silicone composition of the present invention, the amount of (A-2) linear organopolysiloxane having at least 2 silicon atom-bonded alkenyl groups per molecule is 0 to 3% by mass, based on the total mass of all organopolysiloxane components contained in the composition. Specifically, in the curable silicone composition of the present invention, component (A-2) is an optional component, which may or may not be included in the composition. However, when the composition does contain component (A-2), the amount of component (A-2) must be 3% by mass or less, based on the total mass of all organopolysiloxane components contained in the composition. As used in the present specification, the components indicated by “all organopolysiloxane components contained in the composition” are not particularly limited, provided that they are organopolysiloxanes, examples of which include: alkenyl group-containing organopolysiloxanes, which may be linear or resinous; organohydrogenpolysiloxanes, which may be linear or resinous; and other organopolysiloxanes, such as organopolysiloxanes that contain no silicon atom-bonded hydrogen atoms or silicon atom-bonded alkenyl groups. The curable silicone composition may contain only one kind of component (A-2), or may contain two or more kinds of component (A-2).

Component (A-2) has at least 2 silicon atom-bonded alkenyl groups, as well as a monovalent hydrocarbon group that has no silicon atom-bonded aliphatic unsaturated carbon bonds. Examples of alkenyl groups in component (A-2) include C2-12 alkenyl groups such as vinyl, allyl, butenyl, pentenyl, hexenyl, heptenyl, octenyl, nonenyl, decenyl, undecenyl, and dodecenyl groups, where C2-6 alkenyl groups are preferred, and vinyl groups are especially preferred.

Examples of monovalent hydrocarbon groups having no aliphatic unsaturated carbon bonds in component (A-2) include C1-12 alkyl groups such as methyl, ethyl, propyl, isopropyl, butyl, isobutyl, tert-butyl, pentyl, neopentyl, hexyl, cyclohexyl, heptyl, octyl, nonyl, decyl, undecyl, and dodecyl groups; C6-20 aryl groups such as phenyl, tolyl, xylyl, and naphthyl groups; C7-20 aralkyl groups such as benzyl, phenethyl, and phenylpropyl groups; and any of these groups in which some or all of the hydrogen atoms have been substituted with halogen atoms such as fluorine, chlorine, and bromine atoms. The monovalent hydrocarbon groups having no aliphatic unsaturated carbon bonds in component (A-2) are preferably C1-6 monovalent hydrocarbon groups having no aliphatic unsaturated carbon bonds, more preferably C1-6 alkyl groups, and especially preferably methyl groups. In one embodiment, the monovalent hydrocarbon groups in component (A-2) are not aryl-containing groups.

Component (A-2) may have a silicon atom-bonded alkenyl group at just the terminal of the organopolysiloxane molecule (specifically, (R³SiO_{1/2}) unit (M unit), where R is a monovalent hydrocarbon group), or in just diorganosiloxane repeating units of the molecule (specifically, (R²SiO_{2/2}) units (D units), where R is a monovalent hydrocarbon group), or both the terminal of the molecule (M unit) and in diorganosiloxane repeating units (D units).

Component (A-2) can be represented by the following general formula.

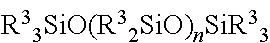

In the formula, R³ is a monovalent hydrocarbon group, at least 2 of R³ are alkenyl groups, and n is an integer of 5 or more.

In the above formula, examples of monovalent hydrocarbon groups represented by R³ include: C1-12 alkyl groups such as methyl, ethyl, propyl, isopropyl, butyl, isobutyl, tert-butyl, pentyl, neopentyl, hexyl, cyclohexyl, heptyl, octyl, nonyl, decyl, undecyl, and dodecyl groups; C6-20 aryl groups such as phenyl, tolyl, xylyl, and naphthyl groups; C7-20 aralkyl groups such as benzyl, phenethyl, and phenylpropyl groups; C2-12 alkenyl groups such as vinyl, allyl, butenyl, pentenyl, hexenyl, heptenyl, octenyl, nonenyl, decenyl, undecenyl, and dodecenyl groups; and any of these groups in which some or all of the hydrogen atoms have been substituted with halogen atoms such as fluorine, chlorine, and bromine atoms. R³ is preferably a C1-6 monovalent hydrocarbon group, more preferably a C1-6 alkyl group, and especially preferably a methyl group. In one embodiment, R³ is a monovalent hydrocarbon group other than an aryl-containing group.

Examples of the at least 2 alkenyl groups represented by R³ in the above formula include C2-12 alkenyl groups such as vinyl, allyl, butenyl, pentenyl, hexenyl, heptenyl, octenyl, nonenyl, decenyl, undecenyl, and dodecenyl groups, where C2-6 alkenyl groups are preferred, and vinyl groups are especially preferred.

In one embodiment of the present invention, component (A-2) can be a linear alkenyl group-containing organopolysiloxane that is capped with the alkenyl groups at both ends of the molecular chain, as represented by the following general formula.

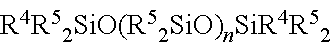

In the formula, R⁴ is an alkenyl group, R⁵ are each independently a monovalent hydrocarbon group having no aliphatic unsaturated carbon bonds, and n is an integer of 5 or more.

In the above formula, R⁴ is an alkenyl group. Examples of alkenyl groups include C2-12 alkenyl groups such as vinyl, allyl, butenyl, pentenyl, hexenyl, heptenyl, octenyl, nonenyl, decenyl, undecenyl, and dodecenyl groups, where C2-6 alkenyl groups are preferred, and vinyl groups are especially preferred.

In the above formula, R⁵ is a monovalent hydrocarbon group having no aliphatic unsaturated carbon bonds. Examples of R⁵ include C1-12 alkyl groups such as methyl, ethyl, propyl, isopropyl, butyl, isobutyl, tert-butyl, pentyl, neopentyl, hexyl, cyclohexyl, heptyl, octyl, nonyl, decyl, undecyl, and dodecyl groups; C6-20 aryl groups such as phenyl, tolyl, xylyl, and naphthyl groups; C7-20 aralkyl groups such as benzyl, phenethyl, and phenylpropyl groups; and any of these groups in which some or all of the hydrogen atoms have been substituted with halogen atoms such as fluorine, chlorine, and bromine atoms. R⁵ is preferably a C1-6 monovalent hydrocarbon group having no aliphatic unsaturated carbon bonds, more preferably a C1-6 alkyl group, and especially preferably a methyl group. In one embodiment, R⁵ is a monovalent hydrocarbon group other than an aryl-containing group.

In the above formula, n is 5 or more, preferably 10 or more, more preferably or more, and even more preferably 30 or more. In one embodiment, n is no more than 3,000, preferably no more than 2,000, and more preferably no more than 1,000.

In one embodiment of the present invention, component (A-2) has a molecular weight of 500 or more. The weight-average molecular weight (Mw) of component (A-2) is not particularly limited, but is preferably 1,000 or more, more preferably 2,000 or more, and even more preferably 3,000 or more. In one embodiment, the weight-average molecular weight (Mw) of component (A-2) is no more than 200,000, preferably no more than 160,000, and even more preferably no more than 120,000.

Component (A-3): Silane Compound or Siloxane Compound that has at Least 2 Silicon Atom-Bonded Alkenyl Groups Per Molecule and that has a Molecular Weight of Less than 500

In one embodiment of the present invention, the curable silicone composition may contain component (A-3), specifically, a silane compound or siloxane compound that has at least 2 silicon atom-bonded alkenyl groups per molecule and that has a molecular weight of less than 500. Examples of component (A-3) include compounds having formula (ViMe₂SiO_{1/2})+(SiO_{4/2}), formula (ViMeSiO_{2/2})₄, and formula

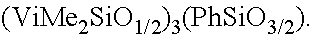

When the curable silicone composition contains component (A-3), the amount of component (A-3) in the composition is preferably such that the [mass of component (A-1)/(mass of component (A-3)+mass of component (A-1))] is 0.3 to 1, more preferably 0.4 to 0.9, and even more preferably 0.5 to 0.8.

### Component (B-1): Resinous Organohydrogenpolysiloxane

The curable silicone composition of the present invention comprises component (B-1), specifically, a resinous organohydrogenpolysiloxane that has at least 2 silicon atom-bonded hydrogen atoms per molecule but does not have any silicon atom-bonded alkenyl groups, wherein the amount of silicon atom-bonded aryl-containing groups is 10 mol % or more, based on the total number of mols of all silicon atom-bonded organic groups. Component (B-1) functions as a crosslinker in the curable silicone composition. The curable silicone composition may contain only one kind of component (B-1), or may contain two or more kinds of component (B-1). Component (B-1) can have a branched or three-dimensional network structure. In component (B-1), the amount of silicon atom-bonded aryl-containing groups is 10 mol % or more, preferably 15 mol % or more, and more preferably 18 mol % or more, based on the total number of mols of all silicon atom-bonded organic groups,

Component (B-1) does not have any silicon atom-bonded alkenyl groups. Examples of silicon atom-bonded groups other than hydrogen atoms in component (B-1) include monovalent hydrocarbon groups that do not contain any aliphatic unsaturated carbon bonds, specific examples of which include C1-12 alkyl groups such as methyl, ethyl, propyl, isopropyl, butyl, isobutyl, tert-butyl, pentyl, neopentyl, hexyl, cyclohexyl, heptyl, octyl, nonyl, decyl, undecyl, and dodecyl groups; C6-20 aryl groups such as phenyl, tolyl, xylyl, and naphthyl groups; C7-20 aralkyl groups such as benzyl, phenethyl, and phenylpropyl groups; and any of these groups in which some or all of the hydrogen atoms have been substituted with halogen atoms such as fluorine, chlorine, and bromine atoms. A small amount of hydroxyl groups, or alkoxy groups such as methoxy or ethoxy groups, may be bonded to silicon atoms in component (B-1), provided that the objective of the present invention is not thereby compromised.

In one embodiment of the present invention, component (B-1) is a resinous organohydrogenpolysiloxane represented by the following average unit formula.

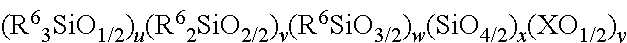

In the formula, R⁶ are each a hydrogen atom or a monovalent hydrocarbon group having no aliphatic unsaturated carbon bonds, and may be the same as or different from each other, except that at least 2 R⁶ per molecule are hydrogen atoms, the amount of silicon atom-bonded aryl-containing groups is 10 mol % or more, based on the total number of mols of all silicon atom-bonded organic groups, X is a hydrogen atom or a C1-10 alkyl group, and u, v, w, x, and y represent the molar ratio of each unit, where 0≤u≤0.8,0≤v≤0.6, 0≤w≤0.8, 0≤x≤y≤0.9, and 0≤y≤0.10, where w+x>0, and u+v+w+x+y=1. Preferably, in the above formula, 0.1≤u≤0.8, 0≤v≤0.5, 0≤w≤0.8, 0≤w≤0.8, and 0≤y≤0.1, where w+x≤0.8 and u+v+w+x+y=1. More preferably 0.2≤w+x≤0.6, and even more preferably w+x≥0.3 and especially ≥0.35.

Specific examples of monovalent hydrocarbon groups represented by R⁶ include C1-12 alkyl groups such as methyl, ethyl, propyl, isopropyl, butyl, isobutyl, tert-butyl, pentyl, neopentyl, hexyl, cyclohexyl, heptyl, octyl, nonyl, decyl, undecyl, and dodecyl groups; C6-12 aryl groups such as phenyl, tolyl, xylyl, and naphthyl groups; C7-12 aralkyl groups such as benzyl, phenethyl, and phenylpropyl groups; and any of these groups in which some or all of the hydrogen atoms have been substituted with halogen atoms such as fluorine, chlorine, and bromine atoms, e.g., halogen-substituted C1-12 alkyl groups such as 3-chloropropyl and 3,3,3-trifluoropropyl groups. Monovalent hydrocarbon groups represented by R⁶ are preferably methyl and phenyl groups. X is preferably a hydrogen atom, a methyl group, or an ethyl group.

In one embodiment of the present invention, component (B-1) can be a resinous organohydrogenpolysiloxane represented by the following average unit formula.

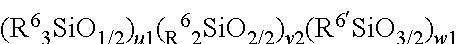

In the formula, R⁶ are each independently a hydrogen atom or a monovalent hydrocarbon group having no aliphatic unsaturated carbon bonds, where at least 2 R⁶ are hydrogen atoms, R⁶′ is a monovalent hydrocarbon group having no aliphatic unsaturated carbon bonds, the amount of silicon atom-bonded aryl-containing groups is 10 mol % or more, based on the total number of mols of all silicon atom-bonded organic groups, u1, v1, and w1 represent the molar ratio of each unit, and denote numbers satisfying 0.1≤u1≤0.8, 0≤v1≤0.5, and 0.1≤w1≤0.8, and u1+v1+w1=1. Examples of monovalent hydrocarbon groups having no aliphatic unsaturated carbon bonds represented by R⁶ include the groups given as examples of monovalent hydrocarbon groups represented by R⁶. In the above average unit formula in one embodiment, v1=0. In the above average unit formula in one embodiment, v1=0, R⁶ is an alkyl group or a hydrogen atom, and preferably a methyl group or a hydrogen atom, and R⁶′ is an aryl group, and preferably a phenyl group.

In one embodiment of the present invention, component (B-1) is represented by the following average unit formula.

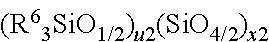

In the formula, R⁶ are the abovementioned monovalent hydrocarbon groups or hydrogen atoms, where at least 2 R⁶ are hydrogen atoms, the amount of silicon atom-bonded aryl-containing groups is 10 mol % or more, based on the total number of mols of all silicon atom-bonded organic groups, u2 and x2 represent the molar ratio of each unit, where 0.1≤u2≤0.8, and 0.25≤x2≤0.9, and preferably 0.5≤u2≤0.7, and 0.3≤x2≤0.5.

In one embodiment of the present invention, the amount of component (B-1) contained in the curable silicone composition, based on the total mass of all organopolysiloxane components contained in the composition, is preferably 1% by mass or more, more preferably 5% by mass or more, and even more preferably 10% by mass or more, while the amount is preferably no more than 30% by mass, more preferably no more than 20% by mass, and even more preferably no more than 25% by mass.

The weight-average molecular weight (Mw) of component (B-1) is not particularly limited, but is preferably 300 or more, more preferably 500 or more, and even more preferably 1000 or more, and is preferably no more than 100,000, more preferably no more than 50,000, and even more preferably no more than 30,000.

### Component (B-2): Linear Organohydrogenpolysiloxane

In one embodiment of the present invention, the curable silicone composition may comprise component (B-2), specifically, a linear organohydrogenpolysiloxane that has at least 2 silicon atom-bonded hydrogen atoms per molecule but does not have any silicon atom-bonded alkenyl groups. Component (B-2) functions as a crosslinker in the curable silicone composition. The curable silicone composition may contain only one kind of component (B-2), or may contain two or more kinds of component (B-2).

Component (B-2) does not have any silicon atom-bonded alkenyl groups. Component (B-2) has a silicon atom-bonded hydrogen atom, as well as a monovalent hydrocarbon group that has no silicon atom-bonded aliphatic unsaturated carbon bonds. In one embodiment of the present invention, component (B-2) can have a silicon atom-bonded aryl-containing group as the monovalent hydrocarbon group. The amount of silicon atom-bonded aryl-containing groups is preferably 5 mol % or more, more preferably 10 mol % or more, and can even more preferably be 15 mol % or more, based on the total number of mols of all silicon atom-bonded organic groups.

Examples of monovalent hydrocarbon groups having no aliphatic unsaturated carbon bonds in component (B-2) include C1-12 alkyl groups such as methyl, ethyl, propyl, isopropyl, butyl, isobutyl, tert-butyl, pentyl, neopentyl, hexyl, cyclohexyl, heptyl, octyl, nonyl, decyl, undecyl, and dodecyl groups; C6-20 aryl groups such as phenyl, tolyl, xylyl, and naphthyl groups; C7-20 aralkyl groups such as benzyl, phenethyl, and phenylpropyl groups; and any of these groups in which some or all of the hydrogen atoms have been substituted with halogen atoms such as fluorine, chlorine, and bromine atoms. The monovalent hydrocarbon group containing no aliphatic unsaturated carbon bonds in component (B-2) is preferably a C1-6 monovalent hydrocarbon group having no aliphatic unsaturated carbon bonds, more preferably 1 or more of any C1-6 alkyl group and a phenyl group, and even more preferably a methyl group and a phenyl group.

Component (B-2) may have a silicon atom-bonded hydrogen atom at just the terminal of the organopolysiloxane molecule (specifically, (R³SiO_{1/2}) unit (M unit), where R is a monovalent hydrocarbon group or a hydrogen atom)), or in just diorganosiloxane repeating units of the molecule (specifically, (R²SiO_{2/2}) units (D units), where R is a monovalent hydrocarbon group or a hydrogen atom), or both the terminal of the molecule (M unit) and in diorganosiloxane repeating units (D units).

Component (B-2) can be represented by the following general formula.

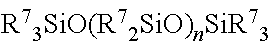

In the formula, R⁷ is a monovalent hydrocarbon group having no aliphatic unsaturated carbon bonds, or is a hydrogen atom, where at least 2 R⁷ are hydrogen atoms, and n is an integer of 1 or more. In the above formula, R⁷ can be an aryl-containing group.

Examples of monovalent hydrocarbon groups represented by R⁷ in the above formula include C1-12 alkyl groups such as methyl, ethyl, propyl, isopropyl, butyl, isobutyl, tert-butyl, pentyl, neopentyl, hexyl, cyclohexyl, heptyl, octyl, nonyl, decyl, undecyl, and dodecyl groups; C6-20 aryl groups such as phenyl, tolyl, xylyl, and naphthyl groups; C7-20 aralkyl groups such as benzyl, phenethyl, and phenylpropyl groups; and any of these groups in which some or all of the hydrogen atoms have been substituted with halogen atoms such as fluorine, chlorine, and bromine atoms. Monovalent hydrocarbon groups represented by R⁷ are preferably methyl and phenyl groups.

In one embodiment of the present invention, component (B-2) can be a linear organohydrogenpolysiloxane that, as represented by the following general formula, has a silicon atom-bonded aryl-containing group, and has silicon atom-bonded hydrogen atoms at both ends of the molecular chain.

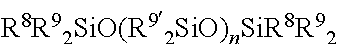

In the formula, R⁸ is a hydrogen atom, R⁹ and R⁹′ are each independently a monovalent hydrocarbon group having no aliphatic unsaturated carbon bonds, and n is an integer of 1 or more. In the above formula, R⁹ and R^{9′} can each independently be an aryl-containing group. The amount of silicon atom-bonded aryl-containing groups is preferably 5 mol % or more, more preferably 10 mol % or more, and can even more preferably be 15 mol % or more, based on the total number of mols of all silicon atom-bonded organic groups.

Examples of R⁹ and R^{9′} include C1-12 alkyl groups such as methyl, ethyl, propyl, isopropyl, butyl, isobutyl, tert-butyl, pentyl, neopentyl, hexyl, cyclohexyl, heptyl, octyl, nonyl, decyl, undecyl, and dodecyl groups; C6-20 aryl groups such as phenyl, tolyl, xylyl, and naphthyl groups; C7-20 aralkyl groups such as benzyl, phenethyl, and phenylpropyl groups; and any of these groups in which some or all of the hydrogen atoms have been substituted with halogen atoms such as fluorine, chlorine, and bromine atoms. R⁹ and R^{9′} are preferably C1-6 monovalent hydrocarbon groups having no aliphatic unsaturated carbon bonds, and more preferably C1-6 alkyl groups or a phenyl group. More preferably, R⁹ and R⁹′ are selected from the group consisting of methyl and phenyl. In one embodiment, R⁹ is an alkyl group, and preferably a methyl group, and R⁹ is an aryl group, and preferably a phenyl group.

In the above formula, n is no more than 2000, more preferably no more than 1500, and even more preferably no more than 1000.

When the curable silicone composition contains component (B-2), the amount of component (B-2) in the composition is preferably such that the [mass of component (B-1)/(mass of component (B-2)+mass of component (B-1))] is 0.1 to 1, more preferably 0.2 to 0.9, and even more preferably 0.5 to 0.8.

The weight-average molecular weight (Mw) of component (B-2) is not particularly limited, but is preferably 300 or more, and more preferably 500 or more, and is preferably no more than 200,000, more preferably no more than 150,000, and even more preferably no more than 100,000.

In the curable silicone composition of the present invention, the [(total number of mols of silicon atom-bonded hydrogen atoms contained in the composition)/(total number of mols of silicon atom-bonded alkenyl groups contained in the composition)>0.5. In the present specification, the above formula may also be referred to as [hydrogen/alkenyl group]. The [hydrogen/alkenyl group] value is preferably more than 0.5 to 1.5, more preferably 0.7 to 1.5, and even more preferably 0.7 to 1.2. Ensuring that the hydrogen/alkenyl group value is greater than 0.5 will result in a cured product having greater hardness.

The alkenyl group content of the components of the curable silicone composition of the present invention can be accurately quantified by the titration method commonly known as the Wijs method. The principles are described below.

The alkenyl groups in the silicone starting material and iodine monochloride are first subjected to addition reaction as shown in formula (1).

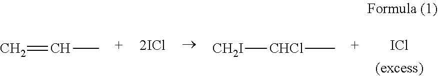

Next, according to the reaction shown in formula (2), the excess amount of iodine monochloride is reacted with potassium iodide and thereby released in the form of iodine.

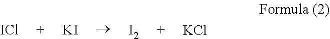

The released iodine is then titrated using sodium thiosulfate solution.

The alkenyl group concentration (mol %) in the component can be quantified from the difference between the amount of sodium thiosulfate required for titration and the amount titrated with separately prepared blank solution. When determining the % by mass, the mol % can by multiplied by the formula mass (in the case of a vinyl group, CH₂=CH— gives a formula mass of 27) to calculate the % by mass.

### Component (C): Hydrosilylation Reaction Catalyst

The curable silicone composition of the present invention comprises component (C), specifically, a hydrosilylation reaction catalyst. The curable silicone composition may contain just one kind of component (C), or may contain two or more kinds of component (C). Component (C) is used as a catalyst to promote the addition reaction (specifically, the hydrosilylation reaction) between the silicon atom-bonded alkenyl groups of the organopolysiloxane and the silicon atom-bonded hydrogen atoms of the organohydrogenpolysiloxane. Examples of component (C) include platinum-based catalysts such as chloroplatinic acid, alcohol solutions of chloroplatinic acid, platinum-olefin complexes, platinum-and-1,3-divinyl-1,1,3,3-tetramethyldisiloxane complexes, and platinum-supporting powders; palladium-based catalysts such as tetrakis(triphenylphosphinc)palladium, and mixtures of triphenylphosphine and palladium black; and rhodium-based catalysts; platinum-based catalysts are particularly preferred.

Component (C) is blended in the amount that is needed to cure the components contained in the curable silicone composition, and is not particularly limited. When, for example, a platinum-based catalyst is used as component (C), the amount of platinum metal contained in the platinum-based catalyst is, for practical purposes, preferably in the range of 0.01 to 1000 ppm, and is in particular preferably in the range of 0.1 to 500 ppm, by weight, in the curable silicone composition.

### Component (D): Hydrosilylation Reaction Inhibitor

In one embodiment of the present invention, the curable silicone composition of the present invention may comprise component (D), specifically, a hydrosilylation reaction inhibitor, as an optional component. Component (D), the hydrosilylation reaction inhibitor, is a component for inhibiting the hydrosilylation reaction of the silicone composition. Specific examples of component (D) include: silylated acetylene compounds such as methyltris(3-methyl-1-butyn-3-oxy)silane, methylvinylbis(3-methyl-1-butyn-3-oxy)silane, and trimethyl(cyclohexyl-1-ethyn-1-oxy)silane; alkyne alcohols such as 1-ethynylcyclohexanol, 2-methyl-3-butyn-2-ol, 3,5-dimethyl-1-hexyn-3-ol, and 2-phenyl-3-butyn-2-ol; enyne compounds such as 3-methyl-3-penten-1-yne and 3,5-dimethyl-3-hexen-1-yne; alkenyl cyclic siloxane compounds such as 1,3,5,7-tetramethyl-1,3,5,7-tetravinylcyclotetrasiloxane and 1,3,5,7-tetramethyl-1,3,5,7-tetrahexenylcyclotetrasiloxane; and benzotriazoles. The content of component (D) in the curable silicone composition is not limited but is normally 0.001 to 5% by mass of the entire curable silicone composition.

### Component (E): White Pigment

In one embodiment, the curable silicone composition of the present invention may comprise component (E), specifically, a white pigment. Examples of component (E) (white pigments) include metal oxides such as titanium oxide, aluminum oxide, zinc oxide, zirconium oxide, and magnesium oxide; hollow fillers such as glass balloons and glass beads; and others, such as barium sulfate, zinc sulfate, barium titanate, aluminum nitride, boron nitride, and antimony oxide. Titanium oxide is preferred because of its high optical reflectance and concealing properties. Aluminum oxide, zinc oxide, and barium titanate are also preferred because of their high optical reflectance in the UV region. The curable silicone composition may contain just one kind of component (E), or may contain two or more kinds of component (E). In one embodiment of the present invention, when the curable silicone composition comprises component (E), the pigment can have a light reflectance of 91% or more, and preferably 93% or more, under the conditions given in the examples (30 μm thick cured product, 450 nm wavelength light).

Component (E) may be a surface-treated white pigment in order to increase the reflectance, whiteness, and light resistance. Examples of types of surface treatments include well-known surface treatments such as treatment with aluminum oxide, aluminum hydroxide, silica, zinc oxide, zirconium oxide, organic compounds, and siloxanes. Examples of organic compounds include, but are not particularly limited to, polyhydric alcohols, alkanolamines or derivatives thereof, organosilicon compounds such as organic siloxanes, higher fatty acids or metal salts thereof, and organometallic compounds. The method of surface treatment is not particularly limited, provided that it is a known method; examples of methods that can be used include (1) methods in which a white pigment that has already been surface treated is mixed into the silicone composition, and (2) methods in which a surface treatment agent is added separately from the white pigment into the silicone composition and reacted with the white pigment in the composition.

The surface treatment of component (E) is not particularly limited, provided that it is a known type, but silica-free treatments are particularly preferred because of the particularly exceptional light resistance of the white cured product that is obtained. Organic substance-free treatments are even more particularly preferred because of the high reflectance that can be maintained following heat resistance tests of the white cured product that is obtained. The white pigment surface treatment can be analyzed using a method of analysis such as scanning electron microscopy with energy-dispersive X-ray analysis (SEM-EDX) or inductively coupled plasma mass spectrometry (ICP-MS).

The average particle size and shape of component (E) are not particularly limited, but the average particle size is preferably in the range of 0.05 to 10 μm, and particularly preferably in the range of 0.1 to 2 μm. As used in the present specification, the average particle size means the particle size of 50% of all particles in the particle size distribution, as determined by laser diffraction/scattering.

Component (E) is an optional component of the curable silicone composition of the present invention, and the content of component (E) is not particularly limited when it is included in the composition. When component (E) is included in the curable silicone composition, the content of component (E) in the curable silicone composition is preferably 50 parts by mass or more, more preferably 75 parts by mass or more, and even more preferably 100 parts by mass or more, per 100 parts by mass of the total of all organopolysiloxane components included in the composition. That is because a component (E) content at or over the above lower limit will result in a cured product that has good optical reflectance. In one embodiment of the present invention, the content of component (E) in the curable silicone composition is preferably 200 parts by mass or less, more preferably 150 parts by mass or less, and even more preferably 120 parts by mass or less, per 100 parts by mass of the total of all organopolysiloxane components included in the composition.

The curable silicone composition of the present invention may include optional components other than the components noted above, provided that the objective of the present invention is not thereby compromised. Examples of optional components include acetylene compounds, organic phosphorus compounds, vinyl group-containing siloxane compounds, inorganic fillers other than white pigments or inorganic fillers that have been hydrophobically surface treated with an organosilicon compound, powder-surface treatment agents or surfactants, organopolysiloxanes containing no silicon atom-bonded hydrogen atoms or silicon atom-bonded alkenyl groups, tackifiers, release agents, metallic soaps, agents that provide heat resistance, agents that provide cold resistance, thermally conductive fillers, agents that provide flame retardance, agents that provide thixotropic properties, fluorescent substances, and solvents.

In one embodiment of the present invention, the curable silicone composition may include organopolysiloxane components other than component (A-1), component (A-2), component (A-3), component (B-1), and component (B-2), provided that the objective of the present invention is not thereby compromised, but the amount of the organopolysiloxane components other than component (A-1), component (A-2), component (A-3), component (B-1), and component (B-2) is preferably 0 to 20% by mass, more preferably 0 to 10% by mass, and even more preferably 0 to 5% by mass, based on the total mass of all organopolysiloxane components included in the composition.

Examples of inorganic fillers include: metal oxide particles such as fumed silica, crystalline silica, precipitated silica, silsesquioxane, magnesium oxide, iron oxide, talc, mica, diatomaceous earth, and glass beads; inorganic fillers such as aluminum hydroxide, magnesium carbonate, calcium carbonate, and zinc carbonate; fibrous fillers such as glass fibers; and fillers such as these fillers that have been hydrophobically surface treated with an organosilicon compound such as an organoalkoxysilane compound, an organochlorosilane compound, an organosilazane compound, or a low molecular-weight siloxane compound. Silicone rubber powder and silicone resin powder, for example, can also be incorporated. The inorganic filler may be blended in an amount of 40% by mass or less, 30% by mass or less, 20% by mass or less, or 10% by mass or less, of the composition.

Examples of powder-surface treatment agents include, but are not particularly limited to, organosilazanes, organocyclosiloxanes, organochlorosilanes, organoalkoxysilanes, low molecular-weight linear siloxanes, and organic compounds. Examples of organic compounds include polyhydric alcohols, alkanolamines or derivatives thereof, organosilicon compounds such as organic siloxanes, higher fatty acids or metal salts thereof, organometallic compounds, organometallic complexes, fluorine-based organic compounds, anionic surfactants, cationic surfactants, and nonionic surfactants.

Tackifiers are preferably organosilicon compounds having at least one silicon atom-bonded alkoxy group per molecule. Examples of alkoxy groups include methoxy, cthoxy, propoxy, butoxy, and methoxy ethoxy groups, where methoxy groups are particularly preferred. Examples of silicon atom-bonded groups other than alkoxy groups in organosilicon compounds include: halogen-substituted or unsubstituted monovalent hydrocarbon groups, alkyl groups, alkenyl groups, aryl groups, aralkyl groups, and alkyl halide groups; glycidoxyalkyl groups such as 3-glycidoxypropyl and 4-glycidoxybutyl groups; epoxycyclohexylalkyl groups such as 2-(3,4-epoxycyclohexyl)ethyl and 3-(3,4-epoxycyclohexyl)propyl groups; epoxyalkyl groups such as 3,4-cpoxybutyl and 7,8-epoxyoctyl groups; acrylic group-containing monovalent organic groups such as 3-methacryloxypropyl groups; and hydrogen atoms. Organosilicon compounds should preferably have a group capable of reacting with alkenyl groups or silicon atom-bonded hydrogen atoms in the composition, specifically, should preferably have a silicon atom-bonded hydrogen atom or alkenyl group.

Organosilicon compounds should also preferably have at least one epoxy group-containing monovalent organic group per molecule as this will allow a variety of base materials to be provided with good adhesiveness. Examples of such organosilicon compounds include organosilane compounds, organosiloxane oligomers, and alkyl silicates. The molecular structure of these organosiloxane oligomers or alkyl silicates may be, for example, linear, linear with some branching, branched, cyclic, or network structures, where linear, branched, and network structures are particularly preferred. Examples of organosilicon compounds include: silane compounds such as 3-glycidoxypropyltrimethoxysilane, 2-(3,4-epoxycyclohexyl)ethyltrimethoxysilane, and 3-methacryloxypropyltrimethoxysilane; siloxane compounds having at least one silicon atom-bonded alkenyl group or silicon atom-bonded hydrogen atom as well as a silicon atom-bonded alkoxy group per molecule; mixtures of a silane compound or siloxane compound having at least one silicon atom-bonded alkoxy group and a siloxane compound having at least one each of a silicon atom-bonded hydroxy group and a silicon atom-bonded alkenyl group per molecule; and methyl polysilicates, ethyl polysilicates, and epoxy group-containing ethyl polysilicates. These tackifiers are preferably in the form of a low-viscosity solution, the viscosity of which is not limited but is preferably in the range of 1 to 500 mPa·s at 25° C. The content of the tackifier is not limited but is preferably in the range of 0.01 to 10 parts by mass per 100 parts by mass of the total of the composition.

Examples of release agents include, but are not particularly limited to, carboxylic acid-based release agents, ester-based release agents, ether-based release agents, ketone-based release agents, and alcohol-based release agents. These may be used alone or in combinations of two or more. Release agents that do or do not contain silicon atoms, or mixtures thereof, can also be used. Specific examples of release agents include carnauba wax, montan wax, calcium stearate, calcium montanate, magnesium stearate, magnesium montanate, zinc stearate, zinc montanate, ester-based waxes, and olefin-based waxes.

The curable silicone composition of the present invention can be prepared by mixing the components. Examples of methods for mixing the components include, but are not particularly limited to, conventionally known methods, but the components can usually simply be mixed to obtain a homogeneous mixture. When solid components such as inorganic filler are included as an optional component, the components are preferably mixed using a mixing device. Examples of such mixing devices include, but are not particularly limited to, single- and twin-screw continuous mixers, double-roll mixers, Ross mixers, Hobart mixers, dental mixers, planetary mixers, kneader mixers, and Henschel mixers.

The curable composition of the present invention can be cured at room temperature or while heated, but heating is preferred in order to ensure rapid curing. The heating temperature is preferably in a range of 50 to 200° C., and more preferably 50 to 90° C. The curable composition of the present invention can be cured rapidly and at low temperatures; for example, the composition can be cured within 20 minutes at 90° C., as determined by the method given in the examples.

### Cured Product

One embodiment of the present invention relates to the cured product of the curable silicone composition. Cured products of the curable silicone composition of the present invention are obtained by curing the curable silicone composition of the present invention. The cured product may be obtained in the form of, but is not particularly limited to, sheets and films, for example. When the cured product is used as a reflective material for optical semiconductor devices, the cured product can be in a form that is suitable for use as a reflective material. The cured product can be used as a stand-alone material but can also be used while incorporated into a base material. When the curable silicone composition of the present invention contains a white pigment, the cured product thereof can have a pencil hardness, as determined via the pencil hardness test given in the examples, of preferably 2B or more, more preferably B or more, and even more preferably F or more. When the cured product of the present invention is a transparent cured product that contains no pigment, the Shore D hardness (the hardness of a sheet-shaped cured product at 25° C., as determined using the Type D durometer specified in the JIS K 6253-1997 “Hardness testing methods for rubber, vulcanized or thermoplastic”) may preferably be 30 or more, and more preferably 40 or more.

### Reflective Material for Optical Semiconductor Devices

One embodiment of the present invention relates to a reflective material for optical semiconductor devices, comprising the cured product of the curable silicone composition. The reflective material for optical semiconductor devices in the present invention can be obtained by curing the curable silicone composition of the present invention. Examples of optical semiconductor devices include, but are not particularly limited to, light emitting diodes (LEDs), semiconductor lasers, photodiodes, phototransistors, solid-state imaging, and light emitters and light receivers for photocouplers, where light emitting diodes (LEDs) are particularly preferred.

### Optical Semiconductor Device

The optical semiconductor device of the present invention is equipped with the reflective material for optical semiconductor devices of the present invention. Examples of optical semiconductor elements include light-emitting diodes (LEDs), semiconductor lasers, photodiodes, phototransistors, solid-state imaging, and light emitters and light receivers for photocouplers, where light-emitting diodes (LEDs) are particularly preferred.

### Examples

The present invention is illustrated in detail by, but is not limited to, the descriptions in the following examples.

The following components were used in the examples and comparative examples. In the following formula, Me represents a methyl group, Vi represents a vinyl group, and Ph represents a phenyl group. The numerical value attached to each unit in the following average unit formula represents the molar ratio of that unit. In the tables, M represents the M unit (Me₃SiO_{1/2}), M(Vi) represents the M unit (ViMe₂SiO_{1/2}), M(H) represents the M unit (HMe₂SiO_{1/2}), D represents the D unit (Me₂SiO_{2/2}), D(Ph₂) represents the D unit (Ph₂SiO_{2/2}), T(Ph) represents the T unit (PhSiO_{3/2}), and Q represents the Q unit (SiO_{4/2}). In the examples, the vinyl group content (% by mass) is the value quantified by the titration method noted above.

Component A-1-1: Resinous alkenyl group-containing organopolysiloxane represented by average unit formula

(ViMe₂SiO_{1/2})_{0.066}(Me₃SiO_{1/2})_{0.409}(SiO_{4/2})_{0.521}(OH)_{0.045}; vinyl group content: 2.6% by mass; weight-average molecular weight (Mw): 5000

Component A-1-2: Resinous alkenyl group-containing organopolysiloxane represented by average unit formula (ViMe₂SiO_{1/2})_{0.15}(Me₃SiO_{1/2})_{0.45}(SiO_{4/2})_{0.40}; vinyl group content: 5.44% by mass

Component A-1-3: Resinous alkenyl group-containing organopolysiloxane represented by average unit formula (ViMe₂SiO_{1/2})_{0.55}(Me₃SiO_{1/2})_{0.05}(SiO_{4/2})_{0.40}; vinyl group content: 18.8% by mass

Component A-2-1: Alkenyl group-containing linear organopolysiloxane represented by average structural formula ViMe₂SiO (Me₂SiO)₁₉₅SiMe₂Vi; vinyl group content: 0.38% by mass

Component A-3-1: Low-molecular weight siloxane compound represented by structural formula (ViMe₂SiO_{1/2})₄(SiO_{4/2}); vinyl group content: 25.0% by mass; molecular weight: 432

Component B-1-1: Phenyl group-containing resinous organohydrogenpolysiloxane represented by average unit formula (HMe₂SiO_{1/2})_{0.6}(PhSiO_{3/2})_{0.4}; silicon atom-bonded hydrogen atom content: 0.65% by mass

Component B-2-1: Phenyl group-containing linear organohydrogenpolysiloxane represented by structural formula (HMe₂SiO_{1/2})₂(Ph₂SiO_{2/2}); silicon atom-bonded hydrogen atom content: 0.60% by mass; molecular weight: 332

Component B-3-1: Phenyl group-free resinous organohydrogenpolysiloxane represented by average unit formula (HMe₂SiO_{1/2})_{0.600}(Me₃SiO_{1/2})_{0.002}(SiO_{4/2})_{0.398}; silicon atom-bonded hydrogen atom content: 0.95% by mass; weight-average molecular weight (Mw): 1600

Component B-3-2: Phenyl group-free linear organohydrogenpolysiloxane represented by average structural formula (HMe₂SiO_{1/2})(Me₂SiO_{2/2})₂₀(HMe₂SiO_{1/2}); silicon atom-bonded hydrogen atom content: 0.14% by mass

Component C-1: Complex of platinum and 1,3-divinyl-1,1,3,3-tetramethyldisiloxane having a platinum concentration of 4.0% by mass

Component D-1: 1-ethynyl-1-cyclohexanol

Component E-1: Titanium dioxide

OE7660: Phenyl-based silicone for LED lighting (produced by Dow Corning)

JCR-6122: Methyl-based silicone for LED lighting (produced by Dow Corning)

Curable silicone compositions were prepared by mixing the components using the formulas (parts by mass) shown in Tables 1 through 3. In Tables 1 through 3, H/Vi expresses the (total number of mols of silicon atom-bonded hydrogen atoms contained in the composition)/(total number of mols of silicon atom-bonded alkenyl groups (specifically, vinyl groups) contained in the composition).

### Evaluation

The curing speed of the compositions, as well as the pencil hardness, reflectance, and refractive index (RI) of the cured products, as determined by the following methods, were determined for each of the compositions in the examples and comparative examples, and the results are presented in Tables 1 through 3.

### Curing Speed of Compositions

Curable silicone composition samples (5.56 g) were analyzed using an MDR (Moving Die Rheometer), where the time taken for the torque to plateau at 90° C. was considered to be the time it took for the entire composition to cure, which was defined as the curing time. A curing time within 20 minutes was considered to be acceptable.

### Pencil Hardness

Curable silicone compositions were applied onto glass plates and were cured by being heated for 20 minutes at 90° C., giving test pieces comprising cured products having a dried thickness of 30 to 50 μm on glass plates. As the cured products on the test pieces were scratched using a pencil at a load of 1000 g and a moving speed of 0.5 mm/s in accordance with JIS K 5400, the next hardness number below the pencil hardness at which the cured product film was damaged at the interface was recorded.

### Reflectance

Curable silicone compositions were applied onto glass substrates and were cured by being heated for 0.5 to 2 hours at 90 to 150° C., giving 30 μm thick cured products. The reflectance (%) of light (450 nm wavelength) on the resulting cured products was determined using a CM-5 Spectrophotometer (produced by Konica Minolta).

### Refractive Index (RI)

Curable silicone compositions were applied onto glass substrates and were cured by being heated for 2 hours at 150° C., giving 30 μm thick cured products. The refractive index of the resulting cured products was determined at 25° C. using an Abbe refractometer. Visible light (589 nm) was used as the light source.

TABLE 1

| | | | | | | | Comparative | Comparative | Comparative |
|---|---|---|---|---|---|---|---|---|---|
| | | Example 1 | Example 2 | Example 3 | Example 4 | Example 5 | Example 1 | Example 2 | Example 3 |
| Components of | B-2-1: M(H)2-D(Ph2) | 7.50 | 6.96 | 4.32 | 1.68 | 10.46 | 13.96 | | |
| the compositions | B-1-1: M(H)60-T(Ph)40 | 7.50 | 6.60 | 9.00 | 11.40 | 3.30 | | | |
| | A-3-1: M(Vi)4-Q | 11.40 | 9.72 | 9.72 | 9.72 | 9.72 | 9.72 | | |
| | A-1-1: M40.9- | 18.39 | 21.51 | 21.75 | 21.99 | 21.31 | 21.11 | | |
| | M(Vi)6.6- | | | | | | | | |
| | Q52.1-(OH)4.5 | | | | | | | | |
| | E-1: Titanium | 55.00 | 55.00 | 55.00 | 55.00 | 55.00 | 55.00 | 55.00 | 55.00 |
| | dioxide | | | | | | | | |
| | C-1: Pt catalyst | 0.02 | 0.02 | 0.02 | 0.02 | 0.02 | 0.02 | | |
| | D-1 1-ethynyl-1- | 0.02 | 0.02 | 0.02 | 0.02 | 0.02 | 0.02 | | |
| | cyclohexanol | | | | | | | | |
| | OE-7660 | | | | | | | 45.00 | |
| | JCR-6122 | | | | | | | | 45.00 |
| Properties | H/Vi | 0.74 | 0.74 | 0.74 | 0.73 | 0.74 | 0.73 | | |
| | Pencil hardness | 2B | B | F | F | F | 5B | >2B | <6B |
| | Reflectance (%) | 93 | 93 | 93 | 93 | 93 | 93 | 90 | 94 |
| | Curing within 20 min at | Pass | Pass | Pass | Pass | Pass | Pass | Fail | Fail |
| | 90° C. | | | | | | | | |

TABLE 2

| | | Example | Example | Example | Comparative | Comparative | Comparative | Comparative | Comparative |
|---|---|---|---|---|---|---|---|---|---|
| | | 6 | 7 | 8 | Example 4 | Example 5 | Example 6 | Example 7 | Example 8 |
| Components of | B-2-1: M(H)2-D(Ph2) | | | | 4.96 | 6.00 | 13.96 | | |
| the | B-1-1: M(H)60-T(Ph)40 | 10.30 | 23.30 | 19.00 | | 6.00 | | | |
| compositions | B-3-1: M0.2M(H)60Q | | | | | | | 13.20 | 6.30 |
| | 39.8 | | | | | | | | |
| | A-2-1: M(Vi)-D195- | | | | 9.00 | | | | |
| | M(Vi) | | | | | | | | |
| | A-3-1: M(Vi)4-Q | | | | | 13.74 | 9.72 | | |
| | A-1-2: M(Vi)15- | 34.49 | | | | | | 31.58 | 38.48 |
| | M(45)-Q40 | | | | | | | | |
| | A-1-3: M(Vi)55- | | 21.49 | 25.79 | | | | | |
| | M(5)-Q40 | | | | | | | | |
| | A-1-1: M40.9- | | | | 30.83 | 19.04 | 21.10 | | |
| | M(Vi)6.6- | | | | | | | | |
| | Q52.1-(OH)4.5 | | | | | | | | |
| | E-1: Titanium | 55.00 | 55.00 | 55.00 | 55.00 | 55.00 | 55.00 | 55.00 | 55.00 |
| | dioxide | | | | | | | | |
| | C-1: Pt catalyst | 0.02 | 0.02 | 0.02 | 0.02 | 0.02 | 0.02 | 0.02 | 0.02 |
| | D-1: 1-ethynyl-1- | 0.20 | 0.20 | 0.20 | 0.20 | 0.20 | 0.20 | 0.20 | 0.20 |
| | cyclohexanol | | | | | | | | |
| Properties | H/Vi | 1.00 | 1.00 | 0.68 | 0.84 | 0.50 | 0.73 | 2.00 | 0.79 |
| | Pencil hardness | HB | 2H | HB | <6B | <6B | 5B | 5B | <6B |
| | Reflectance (%) | 93 | 93 | 93 | 93 | 93 | 93 | 93 | 93 |
| | Curing within 20 min at | Pass | Pass | Pass | Pass | Pass | Pass | Pass | Fail |
| | 90° C. | | | | | | | | |

TABLE 3

| | | Example | Example | Example | Example | Comparative | Comparative | Comparative |
|---|---|---|---|---|---|---|---|---|
| | | 9 | 10 | 11 | 12 | Example 9 | Example 10 | Example 11 |
| Components of the | B-2-1: M(H)2-D(Ph2) | 16.40 | | 11.45 | | | | |
| compositions | B-1-1: M(H)60-T(Ph)40 | 16.40 | 13.36 | 11.45 | 22.90 | | | 21.20 |
| | B-3-1: M0.2M(H)60Q39.8 | | | | | 8.62 | | |
| | B-3-2: M(H)D20M(H) | | | | | 9.62 | 20.67 | |
| | A-2-1: M(Vi)-D195-M(Vi) | | | | | | | |
| | M(VI)-D1100-M(Vi) | | | | | | | 4.00 |
| | A-3-1: M(Vi)4-Q | 24.54 | | | | 10.50 | | |
| | A-1-2: M(Vi)15-M(45)- | | | 76.66 | 76.66 | | | |
| | Q40 | | | | | | | |
| | A-1-3: M(Vi)55-M(5)-Q40 | | | | | | | 19.59 |
| | A-1-1: M40.9-M(Vi)6.6- | 42.20 | 86.20 | | | 16.42 | 24.11 | |
| | Q52.1-(OH)4.5 | | | | | | | |
| | E-1: Titanium dioxide | | | | | 55.00 | 55.00 | 55.00 |
| | C-1: Pt catalyst | 0.04 | 0.04 | 0.04 | 0.04 | 0.02 | 0.02 | 0.02 |
| | D-1: 1-ethynyl-1- | 0.40 | 0.40 | 0.40 | 0.40 | 0.20 | 0.20 | 0.20 |
| | cyclohexanol | | | | | | | |
| Properties | H/Vi | 0.73 | | 1.00 | 1.00 | 0.79 | 1.00 | 1.00 |
| | Pencil hardness | F | | H | H | <6B | <6B | 4B |
| | Reflectance (%) | | | | | 93 | 93 | 93 |
| | Curing within 20 min at 90° C. | Pass | Pass | Pass | Pass | Pass | Pass | Pass |
| | Refractive index | 1.4 | | 1.4 | 1.4 | | | |

Examples 1 through 8 and Comparative Examples 2 and 3 show that the curable silicone compositions of the present invention resulted in cured products that had better overall hardness, reflectance, and low-temperature curing properties than commercially available silicone compositions for LED lighting. Examples 1 through 8 and Comparative Examples 1 and 4 through 8 show that phenyl group-containing resinous organohydrogenpolysiloxanes are needed to obtain a sufficiently hard cured product. Examples 1 through 8 and Comparative Example 5 show that an H/Vi of 0.5 does not allow a sufficiently hard cured product to be obtained even when the composition includes a phenyl group-containing resinous organohydrogenpolysiloxane.

### INDUSTRIAL APPLICABILITY

The curable silicone composition of the present invention can be used to form materials for optical semiconductor devices, and is particularly useful as a material for producing reflective materials for optical semiconductor devices such as light emitting diodes (LEDs), semiconductor lasers, photodiodes, phototransistors, solid-state imaging, and light emitters and light receivers for photocouplers.

1. A curable silicone composition, comprising:
(A-1) a resinous organopolysiloxane having at least 2 silicon atom-bonded alkenyl groups per molecule, that is represented by the following average unit formula: 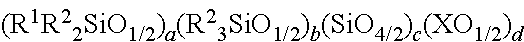
in the formula, R¹ is an alkenyl group, R² is a monovalent hydrocarbon group having no aliphatic unsaturated carbon bonds,
wherein the amount of silicon atom-bonded aryl-containing groups is 0 mol % to less than 10 mol % based on the total number of mols of all silicon atom-bonded organic groups,
X is a hydrogen atom or an alkyl group, and
a, b, c and d represent the molar ratio of each unit, where 0<a≤0.7, 0<b≤0.8, 0<c≤0.7, 0≤d≤0.2, and a+b+c=1.0); and,
(B-1) a resinous organohydrogenpolysiloxane that has at least 2 silicon atom-bonded hydrogen atoms per molecule but does not have any silicon atom-bonded alkenyl groups, wherein the amount of silicon atom-bonded aryl-containing groups is 10 mol % or more based on the total number of mols of all silicon atom-bonded organic groups; and,
(C) a hydrosilylation reaction catalyst,
and wherein
the amount of (A-2) linear organopolysiloxane having at least 2 silicon atom-bonded alkenyl groups per molecule in the composition is 0 to 3% by mass based on the total mass of all organopolysiloxane components contained in the composition, and
(total number of mols of silicon atom-bonded hydrogen atoms contained in the composition)/(total number of mols of silicon atom-bonded alkenyl groups contained in the composition)>0.5.

2. The curable silicone composition according to claim 1, further comprising (A-3) a silane compound or siloxane compound that has at least 2 silicon atom-bonded alkenyl groups per molecule and that has a molecular weight of less than 500, in an amount such that the [mass of component (A-1)/(mass of component (A-3)+mass of component (A-1))] is 0.3 to 1.

3. The curable silicone composition according to claim 1, further comprising (B-2) a linear organohydrogenpolysiloxane that has at least 2 silicon atom-bonded hydrogen atoms per molecule but does not have any silicon atom-bonded alkenyl groups, in an amount such that the [mass of component (B-1)/(mass of component (B-2)+mass of component (B-1))] is 0.1 to 1.

4. The curable silicone composition according to claim 1, further comprising a hydrosilylation reaction inhibitor (D).

5. The curable silicone composition according to claim 1, further comprising a white pigment (E).

6. A cured product of the curable silicone composition according to claim 1.

7. A reflective material for optical semiconductor devices, comprising the cured product of the curable silicone composition according to claim 1.

8. An optical semiconductor device, comprising the reflective material for optical semiconductor devices according to claim 7.
